(19) United States
(12) Patent Application Publication
(10) Pub. No.: US 2008/0042257 A1
(43) Pub. Date: Feb. 21, 2008

(54) DIE PAD ARRANGEMENT AND BUMPLESS CHIP PACKAGE APPLYING THE SAME

(75) Inventor: Chi-Hsing Hsu, Taipei Hsien (TW)

Correspondence Address: J C PATENTS, INC., 4 VENTURE, SUITE 250, IRVINE, CA, 92618, US

(73) Assignee: VIA TECHNOLOGIES, INC., Taipei Hsien (TW)

(21) Appl. No.: 11/846,703

(22) Filed: Aug. 29, 2007

Related U.S. Application Data
(63) Continuation-in-part of application No. 11/248,770, filed on Oct. 11, 2005.

(30) Foreign Application Priority Data
Jul. 15, 2005 (TW) 94124043

(51) Int. Cl. H01L 23/48

(52) U.S. Cl. 257/700; 257/737; 257/E23.02

(57) ABSTRACT

A bumpless chip package including at least one chip and an interconnection structure is provided. The chip has an active surface and a non-active surface opposite the active surface, and has a die pad arrangement disposed on the active surface of the chip. The die pad arrangement includes at least one first pad and at least one second pad. On the active surface of the chip, the projection area of the second pad is greater than that of the first pad. The active surface of chip faces the interconnection structure to embed within the interconnection structure. The interconnection structure has an inner circuit and a plurality of contact pads. The contact pads are disposed on a contact surface of the interconnection structure. Moreover, at least one of the first pad and the second pad is electrically coupled to at least one of the contact pads through the inner circuit.

### CROSS-REFERENCE TO RELATED APPLICATION

This is a continuation-in-part application of patent application Ser. No. 11/248,770, filed on Oct. 11, 2005, which claims the priority benefit of Taiwan application serial no. 94124043, filed on Jul. 15, 2005. The entirety of each of the above-mentioned patent applications is incorporated herein by reference and made a part of this specification.

### BACKGROUND OF THE INVENTION

1. Field of the Invention

The present invention relates to a die pad arrangement, and more particularly, to a die pad arrangement for a bumpless chip package.

2. Description of the Related Art

Along with the continuous development of the electronic technology, in order to fulfill the requirements for electronic components such as the high speed processing, multi-functions, high integration, compact size and lower price, the chip packaging technique is also intensively developed following the trend of miniaturation and high density. A package substrate is usually used by the conventional ball grid array (BGA) packaging technique as a carrier of the integrated circuit (IC) chip, and the chip is electrically coupled to the top surface of the package substrate by using an electrical connecting technique such as the flip chip bonding or the wire bonding and a plurality of solder balls are disposed on the bottom surface of the package substrate with an arrangement of area array. Accordingly, the chip is electrically coupled to an electronic apparatus on the next layer (for example, a printed circuit board (PCB)) through the interconnection of the package substrate and the solder balls on the bottom surface.

However, in the conventional BGA packaging technique it is required to use the package substrate with high layout density and the electrical connecting technique such as the flip chip bonding or the wire bonding, which inevitably causes a long signal transmission path. Accordingly, a bumpless build-up layer (BBUL) chip packaging technique has been developed, which eliminates the fabricating process of the flip chip bonding or the wire bonding. Instead, a multi-layered interconnection structure is formed on the chip directly, and a plurality of electric contacts such as the solder balls or the pins for being electrically coupled to the electronic apparatus on the next level are formed on the multi-layered interconnection structure.

FIG. 1A schematically shows a sectional view of a conventional bumpless chip package. Referring to FIG. 1A, the conventional bumpless chip package 100 includes a chip 110, an interconnection structure 120, a panel-shaped component 130 and a plurality of solder balls 140. Wherein, the chip 110 is disposed on the panel-shaped component 130 and the panel-shaped component 130 is used as a base panel or a supporting layer. FIG. 1B schematically shows a decomposition diagram of the chip and the interconnection structure shown in FIG. 1A. Referring to FIG. 1B, the chip 110 has a plurality of point-shaped pads 112 and the point-shaped pads 112 are disposed on an active surface 114 of the chip 110 with an arrangement of area array. In addition, the point-shaped pads 112 include the signal pads, the ground pads and the power pads.

Referring to FIG. 1A, the interconnection structure 120 formed by a build-up method is disposed on the panel-shaped component 130. In addition, the interconnection structure 120 has an inner circuit 122 and a plurality of contact pads 124. The contact pads 124 are disposed on a contact surface 126 of the interconnection structure 120. It is to be noted that the point-shaped pads 112 are electrically coupled to the contact pads 124 through the inner circuit 122.

The interconnection structure 120 includes a plurality of dielectric layers 128, a plurality of conductive vias 122a and a plurality of conductive layers 122b. Wherein, the inner circuit 122 consists of the conductive vias 122a and the conductive layers 122b. The conductive vias 122a pass through the dielectric layers 128 respectively, and the dielectric layers 128 and the conductive layers 122b are interlaced with each other. Two adjacent conductive layers 122b are electrically coupled to each other by at least one conductive via 122a. In addition, the solder balls 140 for being electrically coupled to an electronic apparatus on the next level (not shown in FIG. 1A) are disposed on the contact pads 124.

However, the size of the power pads and the ground pads on the active surface of the chip are significantly reduced along with the decrease of the chip size, and thus the design is not suitable for chips which require large power supply, such as a CPU. Accordingly, the shape and the arrangement of the point-shaped pads of the chip in the conventional bumpless chip package are desired for further improvement.

### SUMMARY OF THE INVENTION

Therefore, it is an object of the present invention to provide a die pad arrangement, which is applied in the bumpless chip package for increasing the I/O cross-sectional area of the power or ground pad, such that the electric characteristic of the bumpless chip package is improved.

In order to achieve the object mentioned above and others, the present invention provides a die pad arrangement suitable for a chip package. The chip package comprises at least one chip with an active surface and a non-active surface opposite the active surface, and an interconnection structure disposed over the active surface of the chip. The chip includes a top metal layer and a pattern isolation layer on the active surface of the chip. At least portions of the top metal layer exposed by the pattern isolation layer are served as die pads, the die pad arrangement. Wherein, the die pad arrangement includes at least one first pad of the top metal layer and at least one second pad of the top metal layer. In addition, on the active surface of the chip, the projection area of the second pad is greater than that of the first pad, and the second pad is a non-signal pad. At least one of the pads on the active surface of the chip selected from the first pad and the second pad is electrically coupled to the interconnection structure.

In order to achieve the object mentioned above and others, a bumpless chip package including at least one chip and an interconnection structure is provided by the present invention. The chip has an active surface and a non-active surface opposite the active surface, and has a die pad arrangement disposed on the active surface of the chip. The die pad arrangement includes at least one first pad and at least one second pad. The second pad is a non-signal pad. In addition, on the active surface of the chip, the projection area of the second pad is greater than that of the first pad. The active surface of chip faces the interconnection structure to embed within the interconnection structure. The interconnection structure has an inner circuit and a plurality of contact pads. The contact pads are disposed on a contact surface of the interconnection structure. Moreover, at least one of the first pad and the second pad on the active surface of the chip is electrically coupled to at least one of the contact pads through the inner circuit.

In accordance with a preferred embodiment of the present invention, the interconnection structure mentioned above includes, for example but not limited to, a plurality of dielectric layers, a plurality of conductive vias and a plurality of conductive layers. The conductive vias pass through the dielectric layers respectively. Wherein, one terminal of at least one of the conductive vias is electrically coupled to the second pad, and the conductive layers and the dielectric layers are interlaced with each other. In addition, the inner circuit consists of the conductive layers and the conductive vias, and two adjacent conductive layers are electrically coupled to each other by at least one of the conductive vias. Moreover, on a projection surface parallel to the active surface of the chip, a partial extension path of the conductive via electrically coupled to the second pad is overlapped with a projection of an extension path of the second pad on the projection surface.

In summary, in the bumpless chip package provided by the present invention, since the second pad included by the chip is used as the non-signal pad, the I/O cross-sectional area of the non-signal pad (e.g. the power or ground pad) is increased and the current density is reduced, such that the electric characteristic of the bumpless chip package provided by the present invention is further improved.

### BRIEF DESCRIPTION OF THE DRAWINGS

The accompanying drawings are included to provide a further understanding of the invention, and are incorporated in and constitute a part of this specification. The drawings illustrate embodiments of the invention, and together with the description, serve to explain the principles of the invention.

FIG. 1A schematically shows a sectional view of a conventional bumpless chip package.

FIG. 1B schematically shows a decomposition diagram of the chip and the interconnection structure shown in FIG. 1A.

FIG. 2A schematically shows a sectional view of a bumpless chip package according to a first embodiment of the present invention, and FIG. 2B schematically shows the chip of the bumpless chip package of FIG. 2A.

FIG. 3 schematically shows a decomposition diagram of the chip and the interconnection structure shown in FIG. 2A.

FIG. 4 schematically shows a sectional view of a bumpless chip package according to a second embodiment of the present invention.

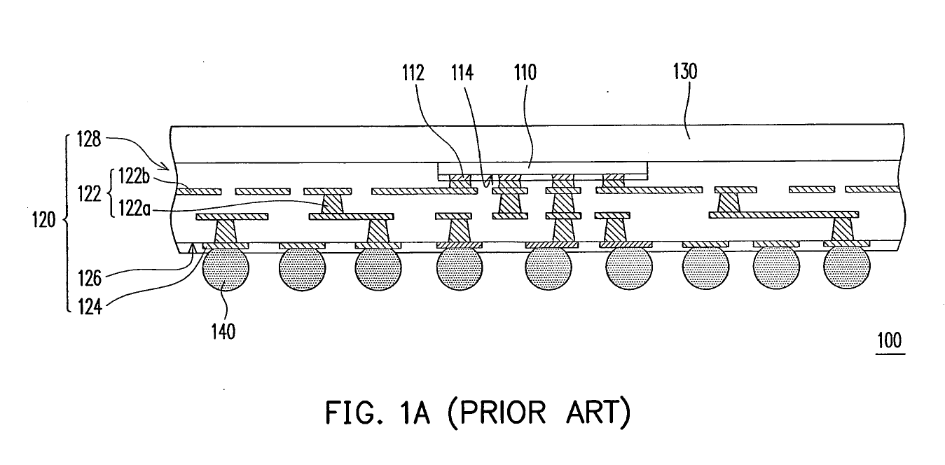

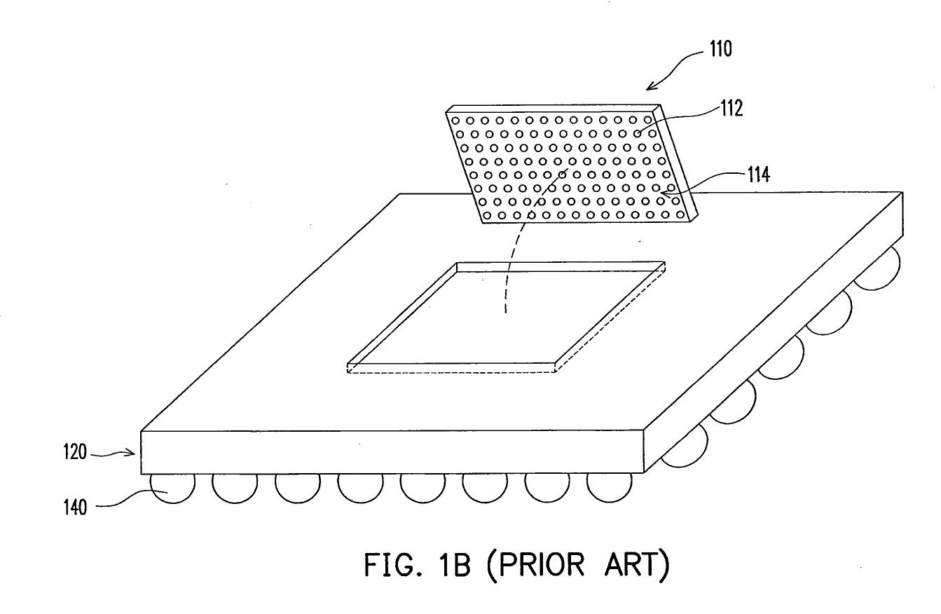

### DESCRIPTION OF THE PREFERRED EMBODIMENTS

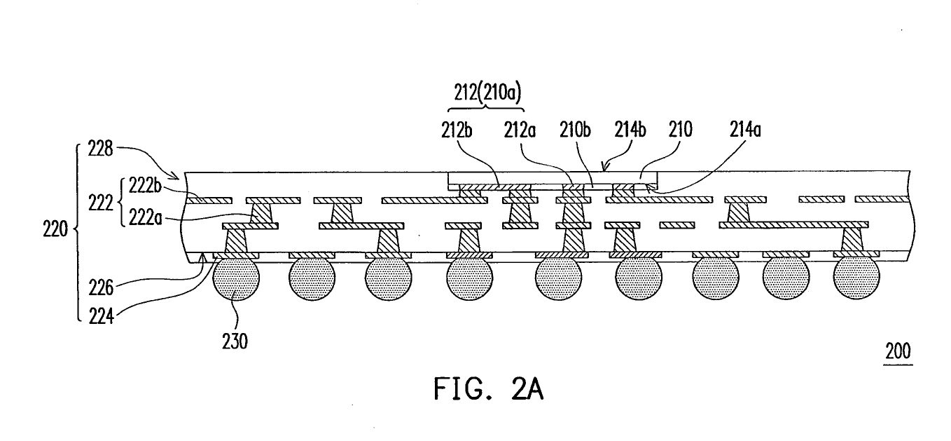

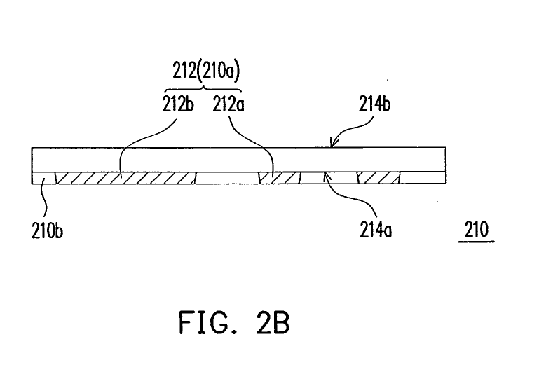

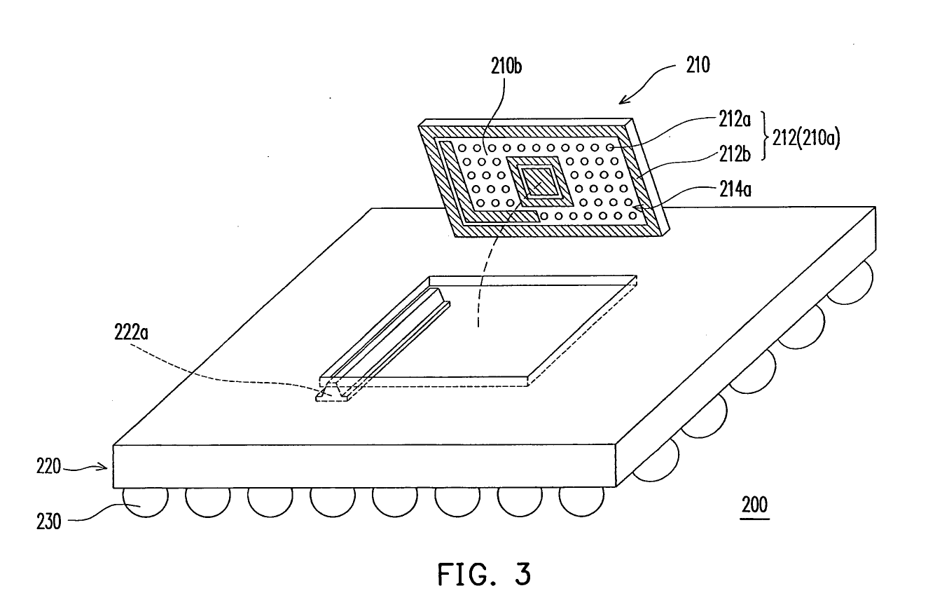

FIG. 2A schematically shows a sectional view of a bumpless chip package according to a first embodiment of the present invention. Referring to FIG. 2A, the bumpless chip package 200 of the present invention includes at least one chip 210 and an interconnection structure 220. The chip 210 has an active surface 214a and a non-active surface 214b opposite the active surface 214a. Referring to FIG. 2B, the chip 210 includes a top metal layer 210a and a pattern isolation layer 210b on the active surface 214a of the chip 210. At least portions of the top metal layer 210a exposed by the pattern isolation layer 210b are served as die pads. The chip 210 has a die pad arrangement 212 (referring to FIG. 3) disposed on an active surface 214a of the chip 210. FIG. 3 schematically shows a decomposition diagram of the chip and the interconnection structure shown in FIG. 2A. Referring to FIG. 3, the die pad arrangement 212 includes at least one first pad 212a and at least one second pad 212b of the top metal layer 210a. The first pads 212a could be point-shaped, and the second pad 212b could be non-point-shaped. On the active surface 214a of the chip 210, the projection area of the second pad 212b is greater than that of one first pad 212a, for example, greater than or equal to that of two first pads 212a. In other words, the second pad 212b could be formed by combining two or more than two neighboring first pads 212a. At least one of the pads on the active surface 214a of the chip 210 selected from the first pad 212a and the second pad 212b is electrically coupled to the interconnection structure 220.

Referring to FIG. 2A and FIG. 3, the chip 210 is embedded within the interconnection structure 220 formed by a build-up process, and the active surface 214a of the chip 210 faces the interconnection structure 220. In addition, the interconnection structure 220 has an inner circuit 222 and a plurality of contact pads 224. The contact pads 224 are disposed on a contact surface 226 of the interconnection structure 220. Moreover, at least one of the first pads 212a on the chip 210 is electrically coupled to at least one of the contact pads 224 through the inner circuit 222. Alternatively, the second pad 2112b on the chip 210 is electrically coupled to at least one of the contact pads 224 through the inner circuit 222.

The interconnection structure 220 includes, for example but not limited to, a plurality of dielectric layers 228, a plurality of conductive vias 222a and a plurality of conductive layers 222b. Wherein, the conductive vias 222a pass through the dielectric layers 228, respectively. In addition, one terminal of at least one of the conductive vias 222a is electrically coupled to the second pad 212b and the conductive layers 222b and the dielectric layers 228 are interleavedly disposed. Moreover, the inner circuit 222 mentioned above consists of the conductive layers 222b and the conductive vias 222a. Two adjacent conductive layers are electrically coupled to each other by at least one of the conductive vias 222a.

Referring to FIG. 3, on a projection surface parallel to the active surface 214a, a partial extension path of the conductive via 222a electrically coupled to the second pad 212b is overlapped with a projection of an extension path of the second pad 212b on the projection surface. In other words, the shape of the conductive via 222a electrically coupled to the second pad 212b may be a slot (FIG. 3 only arbitrarily indicates a strip).

Moreover, if classified by function, at least one of the first pads 212a may be a signal pad or anon-signal pad, and the second pad 212b may be anon-signal pad (e.g. the ground pad, the power pad or other non-signal pad). If classified by shape, the second pad 212b may be a ring-shaped pad, a strip-shaped pad or a block-shaped pad as shown in FIG. 3. It is to be noted that the die pad arrangement 212 of the present embodiment is only for description herein, and the present invention should not be limited by it. In other words, the die pad arrangement 212 may be different due to the various quantities or positions of the first pads 212a and the second pad 212b, or may be different due to the various shapes of the second pads 212b. For example, it may be a combination of any one, any two or any number of the shapes of the various second pads 212b mentioned above.

Referring to FIG. 2A, it is to be noted that if the electric contacts 230 are not disposed to the contact pads 224, the contact pads 224 can be used as the I/O signal interface for the LGA type. In addition, the electric contacts 230 may be disposed on the contact pads 224 respectively, wherein the electric contacts 230 of the present embodiment are conductive balls for providing the I/O signal interface for the BGA type. Moreover, the electric contacts 230 may be conductive pins for providing the I/O signal interface for the PGA type (not shown). Furthermore, the contact pads 224 may belong to the same patterned conductive layer since its fabricating process is the same as that of the conductive layers 222b. According, the conductive layer including the contact pads 224 may be regarded as one of the conductive layers 222b.

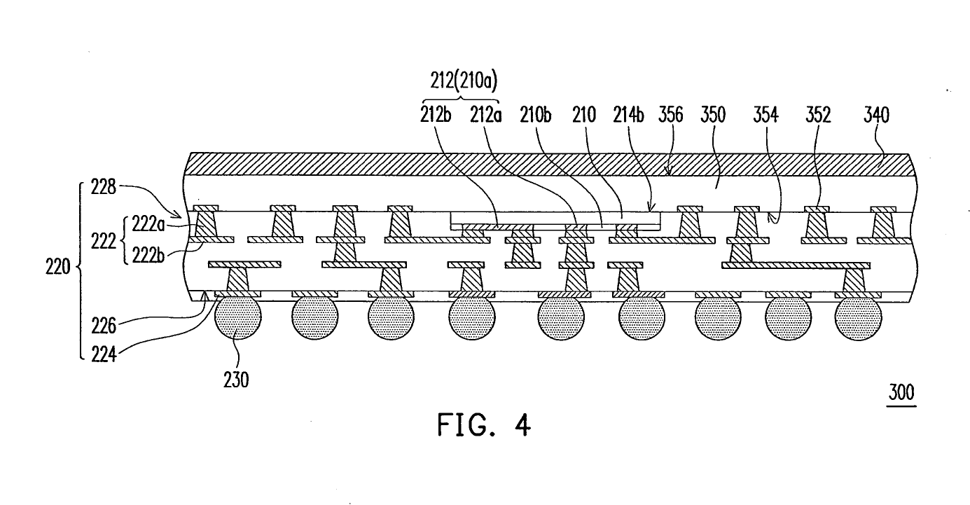

FIG. 4 schematically shows a sectional view of a bumpless chip package according to a second embodiment of the present invention. The difference between the previous and the present embodiments is that the bumpless chip package 300 of the present embodiment further includes a heat spreader 340 and at least one panel-shaped component 350. Wherein, the panel-shaped component 350 is disposed on the non-active surface 214b of the chip 210 and the interconnection structure 220, such that the panel-shaped component 350 herein can be regarded as a carrier for carrying the chip 210. The heat spreader 340 is disposed on a non-electrode surface 356 of the panel-shaped component 350, wherein the non-electrode surface 356 is distant from the chip 210. The spreader 340 is used for rapidly transmitting the heat generated by the chip 210 to the surface of the heat spreader 340. It is to be noted that in some cases, the heat spreader 340 may be directly disposed on the chip 210 and the interconnection structure 220 for eliminating the disposition of the panel-shaped component 350. Alternatively, the chip 210 may be operated in a lower temperature, and in such case the heat spreader 340 is not required. In other words, either the heat spreader 340 or the panel-shaped component 350 may be selectively disposed on the chip 210 and the interconnection structure 220 according to the design requirement. Alternatively, the panel-shaped component 350 and the heat spreader 340 may be sequentially disposed on the chip 210 and the interconnection structure 220.

The panel-shaped component 350 has a plurality of electrodes 352 which are disposed on an electrode surface 354 of the panel-shaped component 350. In addition, at least one of the first pads 212a on the active surface 214a of the chip 210 is electrically coupled to at least one of the electrodes 352 through the inner circuit 222 of the interconnection structure 220. Alternatively, the second pad 212b on the chip 210 may be electrically coupled to one of the electrodes 352 through the inner circuit 222 of the interconnection structure 220. Moreover, at least one of the electrodes 352 is electrically coupled to at least one of the contact pads 224 of the interconnection structure 220 through the inner circuit 222.

The panel-shaped component 350 may be a panel-shaped active component or a panel-shaped passive component. Wherein, the panel-shaped active component may be a panel-shaped transistor and the panel-shaped passive component may be a panel-shaped capacitor, a panel-shaped resistor or a panel-shaped inductor. It is to be noted that the panel-shaped component 350 may has both the active device part and the passive device part, which together form an integrated panel-shaped component. In addition, since the panel-shaped component 350 may be made by either the semiconductor fabricating process or the ceramic fabricating process, the panel-shaped component 350 may be made of a material such as silicon or ceramic.

In summary, in the bumpless chip package provided by the present invention, since the second pad included by the chip is used as the non-signal pad, the I/O cross-sectional area of the power or ground pad is increased and the current density is reduced, such that the electric characteristic of the bumpless chip package provided by the present invention is further improved.

Although the invention has been described with reference to a particular embodiment thereof, it will be apparent to one of the ordinary skill in the art that modifications to the described embodiment may be made without departing from the spirit of the invention. Accordingly, the scope of the invention will be defined by the attached claims not by the above detailed description.

What is claimed is:

1. A die pad arrangement suitable for a chip package, the chip package comprising at least one chip with an active surface and a non-active surface opposite the active surface, and an interconnection structure disposed over the active surface of the chip, wherein the chip includes a top metal layer and a pattern isolation layer on the active surface of the chip, and at least portions of the top metal layer exposed by the pattern isolation layer are served as die pads, the die pad arrangement comprising:
at least one first pad of the top metal layer; and
at least one second pad of the top metal layer, wherein on the active surface of the chip, the projection area of the second pad is greater than that of the first pad, and the second pad is a non-signal pad,
wherein at least one of the pads on the active surface of the chip selected from the first pad and the second pad is electrically coupled to the interconnection structure.

2. The die pad arrangement of claim 1, wherein the first pad is a signal pad or a non-signal pad.

3. The die pad arrangement of claim 1, wherein on the active surface of the chip, the projection area of the second pad is greater than or equal to that of the two first pads.

4. The die pad arrangement of claim 1, wherein the second pad is a ground pad or a power pad.

5. The die pad arrangement of claim 1, wherein the second pad is a ring-shaped pad, a strip-shaped pad or a block-shaped pad.

6. A bumpless chip package, comprising:
at least one chip having an active surface and a non-active surface opposite the active surface, and having a die pad arrangement disposed on the active surface of the chip, wherein the die pad arrangement comprises at least one first pad and at least one second pad, the second pad is a non-signal pad, and on the active surface of the chip, the projection area of the second pad is greater than that of the first pad; and
an interconnection structure which the active surface of the chip faces the interconnection structure to embed within, wherein the interconnection structure has an inner circuit and a plurality of contact pads, the contact pads are disposed on a contact surface of the interconnection structure, and at least one of the pads on the active surface of the chip selected from the first pads and the second pad is electrically coupled to at least one of the contact pads through the inner circuit.

7. The bumpless chip package of claim 6, wherein the interconnection structure comprises:
a plurality of dielectric layers;
a plurality of conductive vias passing through the dielectric layers respectively, wherein one terminal of at least one of the conductive vias is electrically coupled to the second pad; and
a plurality of conductive layers interlaced with the dielectric layers, wherein the inner circuit consists of the conductive layers and the conductive vias, and two adjacent conductive layers are electrically coupled to each other by at least one of the conductive vias.

8. The bumpless chip package of claim 7, wherein on a projection surface parallel to the active surface, a partial extension path of the conductive via electrically coupled to the second pad is overlapped with a projection of an extension path of the second pad on the projection surface.

9. The bumpless chip package of claim 8, wherein the conductive via is a conductive slot.

10. The bumpless chip package of claim 6, wherein the first pad is a signal pad or a non-signal pad.

11. The bumpless chip package of claim 6, wherein on the active surface of the chip, the projection area of the second pad is greater than or equal to that of the two first pads.

12. The bumpless chip package of claim 6, wherein the second pad is a ground pad or a power pad.

13. The bumpless chip package of claim 6, wherein the second pad is a ring-shaped pad, a strip-shaped pad or a block-shaped pad.

14. The bumpless chip package of claim 6, further comprising a heat spreader disposed on the non-active surface of the chip and the interconnection structure.

15. The bumpless chip package of claim 6, further comprising at least one panel-shaped component having a plurality of electrodes disposed on an electrode surface of the panel-shaped component, wherein the panel-shaped component is disposed on the non-active surface of the chip and the interconnection structure, and at least one of the pads on the active surface of the chip selected from the first pad and the second pad is electrically coupled to at least one of the electrodes through the inner circuit.

16. The bumpless chip package of claim 15, wherein at least one of the electrodes is electrically coupled to at least one of the contact pads through the inner circuit.

17. The bumpless chip package of claim 15, further comprising a heat spreader disposed on a non-electrode surface of the panel-shaped component, wherein the non-electrode surface is distant from the chip.

18. The bumpless chip package of claim 15, wherein the panel-shaped component is a panel-shaped active component, a panel-shaped passive component, or a component having both of the active device part and the passive device part.

19. The bumpless chip package of claim 6, further comprising a plurality of electric contacts disposed on the contact pads.

20. The bumpless chip package of claim 19, wherein the electric contacts are a plurality of conductive balls or a plurality of conductive pins.
